(19) United States
(12) Patent Application Publication
(10) Pub. No.: US 2015/0243881 A1
(43) Pub. Date: Aug. 27, 2015

(54) MAGNETIC SHIELDED INTEGRATED CIRCUIT PACKAGE

(71) Applicants: Robert L. Sankman, Phoenix, AZ (US); Dmitri E. Nikonov, Beaverton, OR (US); Jin Pan, Portland, OR (US)

(72) Inventors: Robert L. Sankman, Phoenix, AZ (US); Dmitri E. Nikonov, Beaverton, OR (US); Jin Pan, Portland, OR (US)

(21) Appl. No.: 14/367,153

(22) PCT Filed: Oct. 15, 2013
(86) PCT No.: PCT/US2013/065106

§ 371 Date: May 4, 2015

(51) Int. Cl. H01L 43/02; H01L 43/12; H05K 9/00; G06F 1/16

(52) U.S. Cl. CPC H01L 43/02; G06F 1/1633; H01L 43/12; H05K 9/0075

(57) ABSTRACT

Embodiments of the present disclosure are directed towards magnetic shielded integrated circuit (IC) package assemblies and materials for shielding integrated circuits from external magnetic fields. In one embodiment, a package assembly includes a die coupled with a package substrate and a mold compound disposed on the die. The mold compound includes a matrix component and magnetic field absorbing particles. Other embodiments may be described and/or claimed.

### FIELD

Embodiments of the present disclosure generally relate to the field of integrated circuits, and more particularly, to magnetic shielded integrated circuit package assemblies as well as methods and materials for fabricating magnetic shielded package assemblies.

### BACKGROUND

Emerging memory and logic technologies are using nano-magnetic elements to store and manipulate data. In these magnetic-based systems, logic values may be associated with magnetic dipoles or other magnetic characteristic as opposed to electronic charge or current flow. Such magnetic systems may offer power consumption and performance benefits over traditional memory and logic systems. Magnetic-based systems do, however, introduce new challenges. In particular, the nano-magnetic elements may be susceptible to corruption or errors if exposed to external magnetic fields.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section side view of a package assembly consistent with a flip chip ball grid array (BGA) arrangement, in accordance with some embodiments.

FIG. 2 schematically illustrates cross-section side view of a package assembly including multiple dies in flip chip BGA arrangement, in accordance with some embodiments.

FIG. 3 schematically illustrates a cross-section side view of a package assembly consistent with a fan out wafer level package (FOWLP) or embedded wafer level ball grid array (eWLB) arrangement, in accordance with some embodiments.

FIG. 4 schematically illustrates a cross-section side view of a package assembly consistent with a wire bond ball grid array (WB-BGA) arrangement, in accordance with some embodiments.

FIG. 5 schematically illustrates a cross-section side view of a package assembly consistent with a lead frame based package arrangement, in accordance with some embodiments.

FIG. 6 schematically illustrates a cross-section side view of a package assembly consistent with a bumpless build up layer (BBUL) arrangement, in accordance with some embodiments.

FIG. 7 schematically illustrates a cross-section side view of a package assembly consistent with a three dimensional die bumpless build up layer (BBUL) arrangement in accordance with some embodiments.

FIG. 8 schematically illustrates a cross-section side view of a package assembly consistent with a three dimensional (3D) stacked die bumpless build up layer (BBUL) arrangement including a heat spreader in accordance with some embodiments.

FIG. 9 schematically illustrates a computing device that includes an IC package assembly as described herein, in accordance with some embodiments.

FIG. 10 schematically illustrates a flow diagram of a method of fabricating an IC package assembly, in accordance with some embodiments.

### DETAILED DESCRIPTION

Embodiments of the present disclosure describe magnetic shielded integrated circuit package assemblies, materials for magnetic shielding of integrated circuit package assemblies and methods of fabricating magnetic shielded packaging assemblies. These embodiments are designed to prevent or protect magnetic-based integrated circuits from external magnetic fields to render the magnetic-based devices more robust and allow them to perform in additional environments. In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C). The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” “in embodiments,” or “in some embodiments,” which may each refer to one or more of the same or different embodiments. Furthermore, the terms “comprising,” “including,” “having,” and the like, as used with respect to embodiments of the present disclosure, are synonymous.

The term “coupled with” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

As used herein, the term “module” may refer to, be part of, or include an Application Specific Integrated Circuit (ASIC), an electronic circuit, a system-on-chip (SoC), a processor (shared, dedicated, or group) and/or memory (shared, dedicated, or group) that execute one or more software or firmware programs, a combinational logic circuit, and/or other suitable components that provide the described functionality.

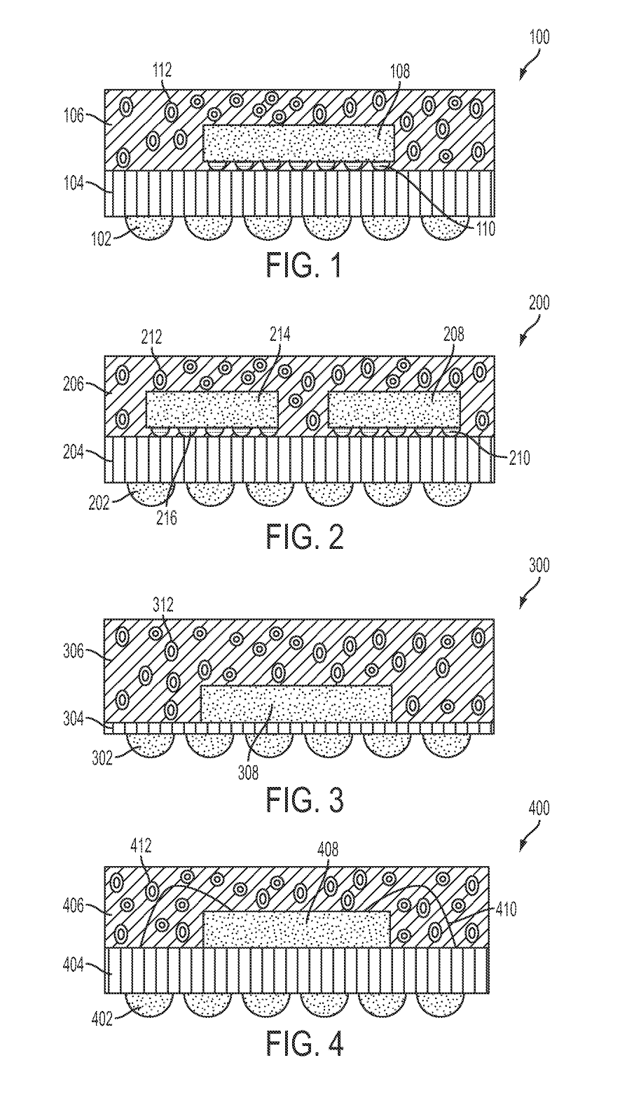

FIG. 1 illustrates a package assembly 100 in accordance with certain embodiments. The package assembly 100 shown in FIG. 1 is consistent with a flip chip BGA arrangement. The package assembly 100 may include a package level interconnect, shown here as ball grid array (BGA) 102. Any suitable package level interconnect may be used. Package assembly 100 may further include a package substrate 104 to which a die 108 may be coupled. Die 108 may contain active and/or passive devices and may include magnetic-based memory or logic. In some embodiments die 108 may include a processor such as an Atom® processor or Quark® processor manufactured by Intel®. Magnetic-based memory or logic may include, but is not limited to, magneto-resistive random-access memory (MRAM), spin torque transfer magneto-resistive random-access memory (STT-MRAM), thermal assisted switching magneto-resistive random-access memory (TAS-MRAM), and spintronic logic. Die 108 may be connected to package substrate 104 via a die level interconnect such as BGA 110. The figures are representative and in practice the package assembly 100 may include additional features that are not specifically discussed herein for clarity. For example, additional structures may exist to electrically couple BGA 110 to package level interconnect (BGA) 102.

The package assembly 100 may include a mold compound (combination of 106 and 112) deposited over the package substrate 104 and the die 108. The mold compound may include a matrix component 106 as well as magnetic field absorbing particles 112. The magnetic field absorbing particles 112 serve to attenuate external magnetic fields and shield the die 108 from such external magnetic fields. The matrix component 106 may include epoxy, other polymeric materials, or any other suitable matrix material. The magnetic field absorbing particles 112 may include ferromagnetic materials such as, for example, iron oxide, nickel iron alloys, or cobalt iron alloys. The magnetic field absorbing particles 112 may also contain small amounts of other elements to enhance the magnetic properties. For example, magnetic field absorbing particles 112 may include “mu metal,” which is typically composed of Ni, In, Cu and Cr. “Mu metal” may have a relative permeability of near 100,000. The magnetic field absorbing particles 112 may include other suitable materials with magnetic permeability characteristics sufficient to attenuate external magnetic fields and shield the die 108 therefrom.

The specific choice of materials and ratio between matrix component 106 and magnetic field absorbing particles 112 depends upon the desired characteristics of the final compound as well as the application and environment in which the package assembly will be used. In general, the higher the concentration of magnetic field absorbing particles 112 the greater the shielding effect and the larger external magnetic fields that may be attenuated. For instance, the concentration of magnetic field absorbing particles 112 may be on the order of 70% by volume. It may be beneficial to utilize concentrations of magnetic field absorbing particles 112 as large as 80%-90% or more by volume for some applications.

In addition to magnetic shielding, thermal properties must be considered when choosing both the matrix component 106 and the magnetic field absorbing particles 112. For instance, the coefficient of thermal expansion of the combined mold compound (combination of 106 and 112) must be similar enough to that of the die 108 and package substrate 104 to ensure proper adhesion and prevent delamination during thermal cycling. Additionally, magnetic field absorbing particles 112 may exhibit a higher thermal conductivity as compared to the matrix component 106. This may result in increase thermal conductivity of the combined mold compound (combination of 106 and 112) which may be beneficial in transporting unwanted heat away from the die 108 or package substrate 104. The magnetic field required to switch a nano-magnet varies depending upon construction of the nano-magnet, but may be on the order to 30 oersteds (Oe). For instance, some nano-magnets are known to require magnetic fields between 30 Oe and 500 Oe to switch. Some environmental (external) magnetic fields overlap with the range required to switch nanomagnets and thus present the possibility of corrupting data stored in magnetic memory or introducing errors in magnetic logic. For instance, a standard refrigerator magnet may produce a magnetic field of 50 Oe, while a solenoid may produce a field of 100 Oe-300 Oe. Given these field values it is possible that such common environmental magnetic fields could have adverse impacts on magnetic memory or magnetic logic. By including magnetic field absorbing particles 112 in the mold compound these environmental magnetic fields can be absorbed and/or attenuated to eliminate and/or diminish any adverse impact on magnetic memory or logic contained in die 108. Although the details of the mold compound are discussed with reference to FIG. 1 they are applicable to each of the embodiments discussed herein.

FIG. 2 illustrates a package assembly 200 in accordance with certain embodiments. The package assembly 200 shown in FIG. 2 is consistent with a flip chip BGA multichip package (FCBGA-MCP) arrangement. The package assembly 200 may include a package level interconnect, shown here as ball grid array (BGA) 202. Any suitable package level interconnect may be used. Package assembly 200 may further include a package substrate 204 to which two dies 208, 214 may be coupled. Dies 208, 214 may contain active and/or passive devices and may include magnetic-based memory or logic as discussed above relative to die 108 in FIG. 1. In some embodiments, dies 208, 214 may include a processor such as, for example, an Atom® processor or Quark® processor manufactured by Intel®. Dies 208, 214 may be connected to package substrate 204 via die level interconnects such as BGAs 210, 216. The package assembly 200 may also include a mold compound (combination of 206 and 212) deposited over the package substrate 204 and the dies 208, 214. The mold compound may include a matrix component 206 and magnetic field absorbing particles 212. The materials and ratios for the mold compound may be selected in accordance with the principles described in connection with FIG. 1.

FIG. 3 illustrates a package assembly 300 in accordance with certain embodiments. The package assembly 300 shown in FIG. 3 is consistent with a fan out wafer level package (FOWLP), also sometimes referred to as an embedded wafer level ball grid array (eWLB), arrangement. The package assembly 300 may include a package level interconnect, shown here as ball grid array (BGA) 302. Any suitable package level interconnect may be used. Package assembly 300 may further include a package substrate 304 to which a die 308 may be coupled.

In the arrangement shown in FIG. 3 package substrate 304 may contain one or more redistribution layers (not shown) as is common in FOWLP/eWLB package assemblies. Die 308 may contain active and/or passive devices and may include magnetic-based memory or logic as discussed above relative to die 108 in FIG. 1. In some embodiments die 308 may include a processor such as an Atom® processor or Quark® processor manufactured by Intel®. Die 308 may be connected to package substrate 304 via any suitable technique. The package assembly 300 may also include a mold compound (combination of 306 and 312) deposited over the package substrate 304 and the die 308. The mold compound may include a matrix component 306 and magnetic field absorbing particles 312. The materials and ratios for the mold compound may be selected in accordance with the principles described in connection with FIG. 1.

FIG. 4 illustrates a package assembly 400 in accordance with certain embodiments. The package assembly 400 shown in FIG. 4 is consistent with wire bond BGA (WB-BGA) arrangement. The package assembly 400 may include a package level interconnect, shown here as ball grid array (BGA) 402. Any suitable package level interconnect may be used. Package assembly 400 may further include a package substrate 404 to which a die 408 may be coupled. Die 408 may be electrically coupled to the package level interconnect (BGA) 402 via wires 410. Wires 410 may electrically couple a contact on die 408 to a conductive path (not specifically shown) formed through the package substrate 404 to the BGA 402. Die 408 may contain active and/or passive devices and may include magnetic-based memory or logic as discussed above relative to die 108 in FIG. 1. In some embodiments die 408 may include a processor such as an Atom® processor or Quark® processor manufactured by Intel®. Die 408 may be connected to package substrate 404 via any suitable technique. The package assembly 400 may also include a mold compound (combination of 406 and 412) deposited over the package substrate 404 and the die 408. The mold compound may include a matrix component 406 and magnetic field absorbing particles 412. The materials and ratios for the mold compound may be selected in accordance with the principles described in connection with FIG. 1.

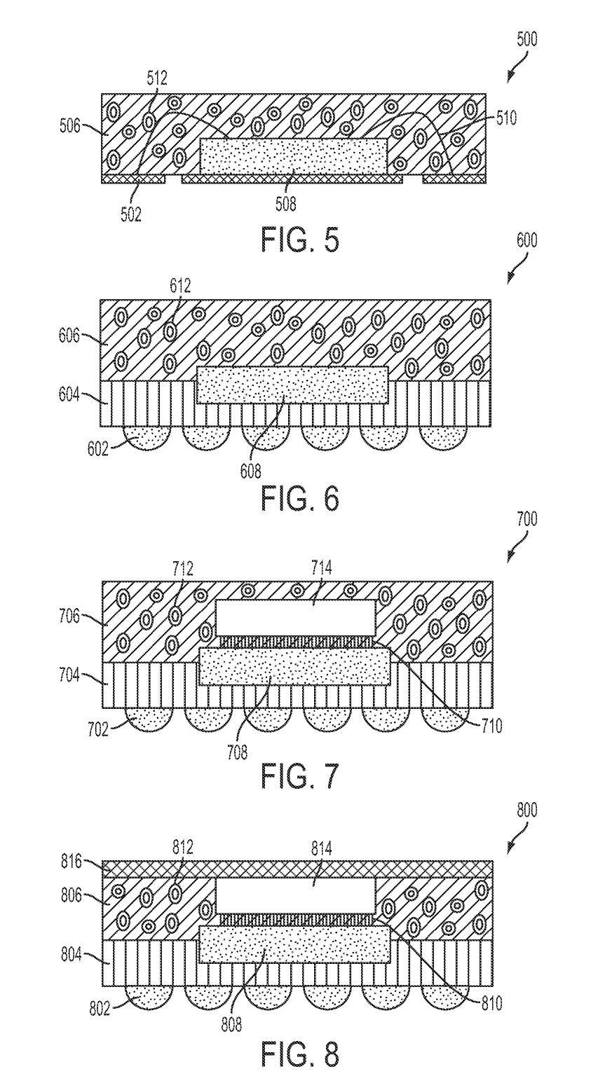

FIG. 5 illustrates a package assembly 500 in accordance with certain embodiments. The package assembly 500 shown in FIG. 5 is consistent with a lead frame based package arrangement. The package assembly 500 may include a package level interconnect, shown here as lead frame 502. Any suitable package level interconnect may be used. Package assembly 500 may further include a die 508 coupled to lead frame 502. Die 508 may contain active and/or passive devices and may include magnetic-based memory or logic as discussed above relative to die 108 in FIG. 1. In some embodiments, die 508 may include a processor such as an Atom® processor or Quark® processor manufactured by Intel®. Die 508 may be connected to lead frame 502 via any suitable technique. Die 508 may be electrically coupled to lead frame 502 via wires 510. The package assembly 500 may also include a mold compound (combination of 506 and 512) deposited over the lead frame 502 and the die 508. The mold compound may include a matrix component 506 and magnetic field absorbing particles 512. The materials and ratios for the mold compound may be selected in accordance with the discussion provided above relative to FIG. 1.

FIG. 6 illustrates a package assembly 600 in accordance with certain embodiments. The package assembly 600 shown in FIG. 6 is consistent with a bumpless build up layer (BBUL) arrangement. The package assembly 600 may include a package level interconnect, shown here as ball grid array (BGA) 602. Any suitable package level interconnect may be used. Package assembly 600 may further include a package substrate 604 to which a die 608 may be coupled or embedded into as shown. Die 608 may contain active and/or passive devices and may include magnetic-based memory or logic as discussed above relative to die 108 in FIG. 1. In some embodiments die 608 may include a processor such as an Atom® processor or Quark® processor manufactured by Intel®. Die 608 may be connected to package substrate 604 via any suitable technique. The package assembly 600 may also include a mold compound (combination of 606 and 612) deposited over the package substrate 604 and the die 608. The mold compound may include a matrix component 606 and magnetic field absorbing particles 612. The materials and ratios for the mold compound may be selected in accordance with the principles described in connection with FIG. 1.

FIG. 7 illustrates a package assembly 700 in accordance with certain embodiments. The package assembly 700 shown in FIG. 7 is consistent with a three dimensional (3D) stacked die bumpless build up layer (BBUL) arrangement. The package assembly 700 may include a package level interconnect, shown here as ball grid array (BGA) 702. Any suitable package level interconnect may be used. Package assembly 700 may further include a package substrate 704 to which a die 708 may be coupled or embedded into as shown. Die 708 may contain active and/or passive devices and may include magnetic-based memory or logic as discussed above relative to die 108 in FIG. 1. In some embodiments, die 708 may include a processor such as an Atom® processor or Quark® processor manufactured by Intel®. Die 708 may be connected to package substrate 704 via any suitable technique. The package assembly 700 may also include a second die 714 mounted on the first die 708. The second die 714 may be electrically coupled to the first die 708 by one or more pillars 710 or by other suitable connection techniques. Second die 714 may contain active and/or passive devices similar to first die 708. In some embodiments first die 708 may contain a processor while second die 714 may contain primarily memory. The package assembly 700 may also include a mold compound (combination of 706 and 712) deposited over the package substrate 704 and the dies 708, 714. The mold compound may include a matrix component 706 and magnetic field absorbing particles 712. The materials and ratios for the mold compound may be selected in accordance with the principles described in connection with FIG. 1.

FIG. 8 illustrates a package assembly 800 in accordance with certain embodiments. The package assembly 800 shown in FIG. 8 is consistent with a three dimensional die bumpless build up layer (BBUL) arrangement including a heat spreader. The package assembly 800 may include a package level interconnect, shown here as ball grid array (BGA) 802. Any suitable package level interconnect may be used. Package assembly 800 may further include a package substrate 804 to which a die 808 may be coupled or embedded into as shown. Die 808 may contain active and/or passive devices and may include magnetic-based memory or logic as discussed above relative to die 108 in FIG. 1. In some embodiments, die 808 may include a processor such as an Atom® processor or Quark® processor manufactured by Intel®. Die 808 may be connected to package substrate 804 via any suitable technique. The package assembly 800 may also include a second die 814 mounted on the first die 808. The second die 814 may be electrically coupled to the first die 808 by one or more pillars 810 or by other suitable connection techniques. Second die 814 may contain active and/or passive devices similar to die 808. In some embodiments first die 808 may contain a processor while second die 814 may contain primarily memory.

The package assembly 800 may further include a heat spreader 816. Heat spreader 816 may be attached to second die 814 to transport heat away from second die 814. The package assembly 800 may also include a mold compound (combination of 806 and 812) deposited over the package substrate 804 and the dies 808, 814. The mold compound may include a matrix component 806 and magnetic field absorbing particles 812. The materials and ratios for the mold compound may be selected in accordance with the principles described in connection with FIG. 1. As discussed above the magnetic field absorbing particles 812 may have beneficial thermal conductivity characteristics in addition to their magnetic shielding capabilities. The magnetic field absorbing particles 812 may facilitate transfer of heat away from package substrate 804 as well as dies 808, 814. The magnetic field absorbing particles 812 may help transfer heat to a heat spreader 816 or to the environment where convective cooling is more readily available. For instance, magnetic field absorbing particles 812 may provide thermal pathways for removing heat from package substrate 804 as well as dies 808, 814. Magnetic field absorbing particles 812 may form generally vertical thermal pathways to transfer heat from package substrate 804, as well as die 808, to heat spreader 816. Magnetic field absorbing particles 812 may also form generally horizontal thermal pathways to transfer heat from package substrate 804 as well as dies 808, 814 to the ambient environment (for example at the left and right edges of 806 in FIG. 8). As dies (e.g., processors) continue to shrink to smaller dimensions (e.g., Atom® processor or Quark® processor manufactured by Intel®), a localized hot spot of a smaller die in operation may include a larger area of the die including, for example, substantially all or all of an area (e.g., active side) of a die. The magnetic field absorbing particles 812 may be dispersed in the mold compound around substantially all or all of the area of the die to facilitate heat transfer away from the hot spot of smaller dies. Although a heat spreader is not specifically shown in other figures, one or more heat spreaders may be included in any embodiment.

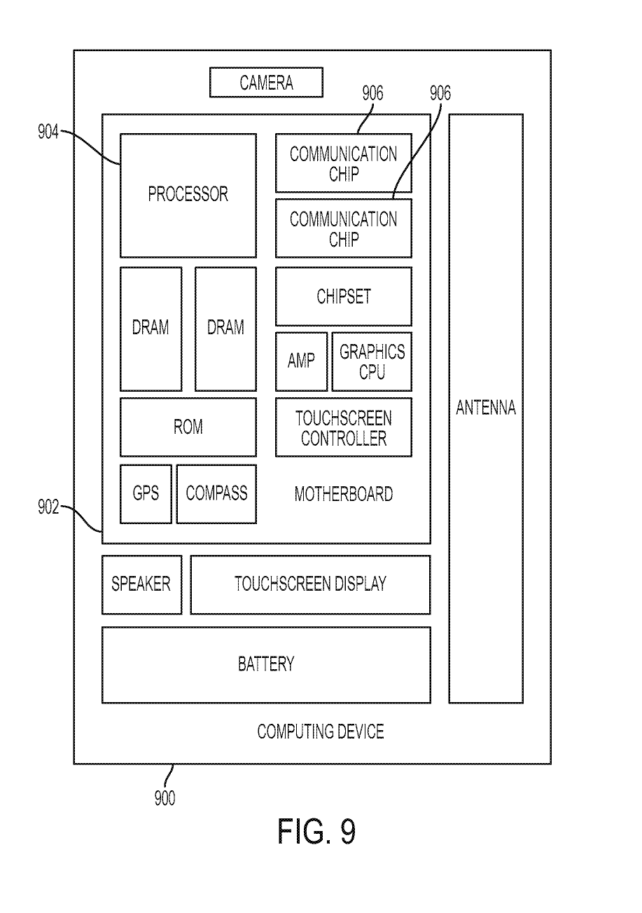

Embodiments of the present disclosure may be implemented into a system using any suitable hardware and/or software to configure as desired. FIG. 9 schematically illustrates a computing device 900 that includes an IC package assembly (e.g., one or more of package assemblies 100-800 of FIGS. 1-8) as described herein, in accordance with some embodiments. The computing device 900 may include housing to house a board such as motherboard 902.

Motherboard 902 may include a number of components, including but not limited to processor 904 and at least one communication chip 906. Processor 904 may be physically and electrically coupled to motherboard 902. In some implementations, the at least one communication chip 906 may also be physically and electrically coupled to motherboard 902. In further implementations, communication chip 906 may be part of processor 904.

Depending on its applications, computing device 900 may include other components that may or may not be physically and electrically coupled to motherboard 902. These other components may include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth).

Communication chip 906 may enable wireless communications for the transfer of data to and from computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 906 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible BWA networks are generally referred to as WiMAX networks, an acronym that stands for Worldwide Interoperability for Microwave Access, which is a certification mark for products that pass conformity and interoperability tests for the IEEE 802.16 standards. Communication chip 906 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 906 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 906 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. Communication chip 906 may operate in accordance with other wireless protocols in other embodiments.

Computing device 900 may include a plurality of communication chips 906. For instance, a first communication chip 906 may be dedicated to shorter range wireless communications such as Wi-Fi and Bluetooth, and a second communication chip 906 may be dedicated to longer range wireless communications such as GPS, EDGE, GPRS, CDMA, WiMAX, LTE, Ev-DO, and others.

Processor 904 of computing device 900 may be packaged in an IC assembly (e.g., package assemblies 100-800 of FIGS. 1-8) as described herein. For example, processor 904 may correspond with one of dies 108-808. In some embodiments, processor 904 may include an Atom® processor or Quark® processor manufactured by Intel®. The package assembly (e.g., package assemblies 100-800 of FIGS. 1-8) and motherboard 902 may be coupled together using package-level interconnects such as BGA balls (e.g., 102 of FIG. 2) or lead frame 502. The term “processor” may refer to any device or portion of a device that processes electronic data from registers and/or memory to transform that electronic data into other electronic data that may be stored in registers and/or memory.

Communication chip 906 may also include a die (e.g., dies 108-808 of FIGS. 1-8) that may be packaged in an IC assembly (e.g., package assemblies 100-800 of FIGS. 1-8) as described herein. In further implementations, another component (e.g., memory device or other integrated circuit device) housed within computing device 900 may include a die (e.g., dies 108-808 of FIGS. 1-8) that may be packaged in an IC assembly (e.g., package assemblies 100-800 of FIGS. 1-8) as described herein.

Computing device 900 may contain a module that generates a magnetic field that could potentially disrupt the function of magnetic memory or magnetic logic included in that module or other modules of computing device 900. For instance, computing device 900 may include a hard drive that generates a magnetic field. The mold compound discussed herein, included in package assemblies 100-800 of FIGS. 1-8, is designed to absorb external magnetic fields such as those generated by other modules of computing device 900 and thus shield the dies included in package assembly utilizing the molding compound from the adverse impact of such external magnetic fields.

In various implementations, computing device 900 may be a laptop, a netbook, a notebook, an Ultrabook™, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 900 may be any other electronic device that processes data.

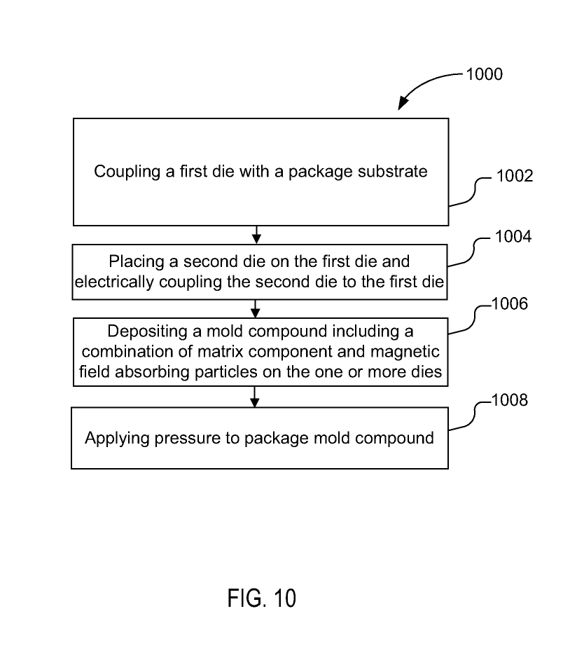

FIG. 10 schematically illustrates a flow diagram of a method 1000 of fabricating an IC package assembly (e.g., package assemblies 100-800 of FIGS. 1-8), in accordance with some embodiments.

At 1002 the method 1000 may include coupling a first die (e.g., dies 108-808 of FIGS. 1-8) with a package substrate. Any suitable technique may be used to attach the die to the package substrate consistent with the package assemblies discussed relative to FIGS. 1-8 above, as well any other suitable techniques for additional package assemblies not specifically discussed herein.

At 1004 the method 1000 may include placing a second die (e.g., dies 714 and 814 of FIGS. 7-8) on the first die and electrically coupling the second die to the first die. The second die may be electrically coupled to the first die as part of the placement of the second die or by another separate operation. Any suitable techniques may be used to attach the second die and electrically couple the second die to the first die. This action is optional in some embodiments and results in three dimensional stacked die arrangements such as those shown in FIGS. 7 and 8.

At 1006 the method 1000 may include depositing a mold compound (e.g., combination of matrix components 106-806 and magnetic field absorbing particles 112-812 of FIGS. 1-8) over the one or more dies. As discussed previously the mold compound may contain a matrix component and magnetic field absorbing particles (e.g., magnetic field absorbing particles 112-812 of FIGS. 1-8). The matrix component may include epoxy, other polymeric materials, or any other suitable matrix material. The magnetic field absorbing particles may include ferromagnetic materials such iron oxide, nickel iron alloys, or cobalt iron alloys. The magnetic field absorbing particles may include other suitable materials with magnetic permeability characteristics sufficient to attenuate external magnetic fields and shield the die therefrom.

At 1008 the method 1000 may include applying pressure to the mold compound. The application of pressure may force the mold compound into voids that exist after the deposition of the mold compound in order to ensure sufficient contact and adhesion to the underlying components such as the die. The application of pressure may also compact the mold compound changing the density and final thickness as well other properties of the mold compound. The pressure may be applied over a range of temperatures including elevated temperatures. Applying pressure at elevated temperature may result in better processing characteristics of the mold compound as well as desired final properties. The pressure and temperature may be varied depending on the specific materials and ratios thereof being used as well as on the final application or environment of the package assembly under construction.

Various operations are described as multiple discrete operations in turn, in a manner that is most helpful in understanding the claimed subject matter. However, the order of description should not be construed as to imply that these operations are necessarily order dependent.

### Examples

According to various embodiments, the present disclosure describes an apparatus (e.g., a package assembly) including a magnetic shielded integrated circuit. Example 1 of the apparatus includes a die coupled with a package substrate; and a mold compound disposed on the die; wherein the mold compound includes a matrix component and particles to absorb a magnetic field. Example 2 includes the apparatus of Example 1, wherein the mold compound comprises at least 70% by volume particles to absorb a magnetic field. Example 3 includes the apparatus of Example 2, wherein the mold compound comprises at least 80% by volume particles to absorb a magnetic field. Example 4 includes the apparatus of any of Examples 1-3, wherein the matrix component comprises an epoxy material. Example 5 includes the apparatus of any of Examples 1-3, wherein the particles to absorb a magnetic field comprise a ferromagnetic material. Example 6 includes the apparatus of any of Examples 1-3, wherein the particles to absorb a magnetic field provide a thermal pathway through the mold compound to transfer heat away from the die. Example 7 includes the apparatus of any of Examples 1-3, wherein the die coupled with the package substrate is a first die at least partially embedded in the package substrate and the package assembly further comprises a second die disposed on and electrically coupled to the first die. Example 8 includes the apparatus of any of Examples 1-3, wherein the die comprises at least one of magnetic memory or magnetic logic. Example 9 includes the apparatus of any of Examples 1-3, wherein the particles to absorb a magnetic field comprise a material selected from the group consisting of iron oxide, nickel iron alloys, cobalt iron alloys and a combination of Ni, In, Cu and Cr. Example 10 includes the apparatus of any of Examples 1-3, wherein the particles to absorb a magnetic field comprise at least one of iron oxide, nickel iron alloys, cobalt iron alloys and a combination of Ni, In, Cu and Cr.

According to various embodiments, the present disclosure describes a method of fabricating a package assembly. Example 10 includes a method comprising: coupling at least one die with a package substrate; and depositing a mold compound over the at least one die; wherein the mold compound includes a matrix component and particles to absorb a magnetic field. Example 11 includes the method of Example 10, wherein the mold compound comprises at least 70% by volume particles to absorb a magnetic field. Example 12 includes the method of Example 11, wherein the mold compound comprises at least 80% by volume particles to absorb a magnetic field. Example 13 includes the method of any of Examples 10-12, wherein the matrix component comprises an epoxy material. Example 14 includes the method of any of Examples 10-12, wherein the particles to absorb a magnetic field comprise a ferromagnetic material. Example 15 includes the method of any of Examples 10-12, wherein coupling the at least one die with the package substrate includes at least partially embedding a first die in the package substrate and the method further comprises placing a second die on the first die prior to depositing the mold compound.

According to various embodiments, the present disclosure describes a material (e.g., mold compound) for magnetically shielding integrated circuit assemblies. Example 16 includes a mold compound for magnetically shielding integrated circuit assemblies comprising: a matrix component; and at least 70% by volume particles to absorb a magnetic field. Example 17 includes the material of Example 16, wherein the at least 70% by volume particles to absorb a magnetic field is at least 80% by volume. Example 18 includes the material of Examples 16 or 17, wherein the particles to absorb a magnetic field comprise a ferromagnetic material. Example 18 includes the material of Examples 16 or 17, wherein the matrix component comprises an epoxy material.

According to various embodiments, the present disclosure describes system (e.g., a computing device) including a magnetic shielded integrated circuit. Example 20 includes a computing device comprising: a circuit board; and a package assembly having a first side and a second side disposed opposite to the first side, the first side being coupled with the circuit board using one or more package-level interconnects disposed on the first side, the package assembly including a die coupled with a package substrate; and a mold compound disposed on the die; wherein the mold compound includes a matrix component and particles to absorb a magnetic field. Example 21 includes the computing device of Example 20, wherein the mold compound comprises at least 70% by volume particles to absorb a magnetic field. Example 22 includes the computing device of

Example 20, wherein the mold compound comprises at least 80% by volume particles to absorb a magnetic field. Example 23 includes the computing device of any of Examples 20-22, wherein the die coupled with the package substrate is a first die at least partially embedded in the package substrate and the package assembly further comprises a second die disposed on and electrically coupled to the first die. Example 24 includes the computing device of any of Examples 20-22, wherein the computing system further comprises a module that generates a magnetic field; wherein the particles to absorb a magnetic field are configured to shield the die from the magnetic field. Example 25 includes the computing device of any of Examples 20-22, wherein the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated implementations, including what is described in the Abstract, is not intended to be exhaustive or to limit the embodiments of the present disclosure to the precise forms disclosed. While specific implementations and examples are described herein for illustrative purposes, various equivalent modifications are possible within the scope of the present disclosure, as those skilled in the relevant art will recognize.

These modifications may be made to embodiments of the present disclosure in light of the above detailed description. The terms used in the following claims should not be construed to limit various embodiments of the present disclosure to the specific implementations disclosed in the specification and the claims. Rather, the scope is to be determined entirely by the following claims, which are to be construed in accordance with established doctrines of claim interpretation.

1. A package assembly comprising:
a die coupled with a package substrate; and
a mold compound disposed on the die and the package substrate;
wherein the mold compound includes a matrix component and particles to absorb a magnetic field.

2. The package assembly of claim 1, wherein:
the mold compound comprises at least 70% by volume particles to absorb a magnetic field.

3. The package assembly of claim 1, wherein:
the mold compound comprises at least 80% by volume particles to absorb a magnetic field.

4. The package assembly of claim 1, wherein:
the matrix component comprises an epoxy material.

5. The package assembly of claim 1, wherein:
the particles to absorb a magnetic field comprise a ferromagnetic material.

6. The package assembly of claim 1, wherein:
the particles to absorb a magnetic field are to provide a thermal pathway through the mold compound to transfer heat away from the die.

7. The package assembly of any of claim 1, wherein:
the die coupled with the package substrate is a first die at least partially embedded in the package substrate and the package assembly further comprises a second die disposed on and electrically coupled to the first die.

8. The package assembly of claim 1, wherein:
the die comprises at least one of magnetic memory or magnetic logic.

9. The package assembly of claim 1, wherein the particles to absorb a magnetic field comprise at least one of iron oxide, nickel iron alloys, cobalt iron alloys and a combination of Ni, In, Cu and Cr.

10. A method of fabricating a package assembly, the method comprising:
coupling at least one die with a package substrate; and
depositing a mold compound over the at least one die;
wherein the mold compound includes a matrix component and particles to absorb a magnetic field.

11. The method of claim 10, wherein:
the mold compound comprises at least 70% by volume particles to absorb a magnetic field.

12. The method of claim 11, wherein:
the mold compound comprises at least 80% by volume particles to absorb a magnetic field.

13. The method of claim 10, wherein:
the matrix component comprises an epoxy material.

14. The method of claim 10, wherein:
the particles to absorb a magnetic field comprise a ferromagnetic material.

15. The method of claim 10, wherein:
coupling the at least one die with the package substrate includes at least partially embedding a first die in the package substrate and the method further comprises placing a second die on the first die prior to depositing the mold compound.

16. A mold compound for magnetically shielding integrated circuit assemblies comprising:
a matrix component; and
at least 70% by volume particles to absorb a magnetic field.

17. The mold compound of claim 16, wherein:
the at least 70% by volume particles to absorb a magnetic field is at least 80% by volume.

18. The mold compound of claim 16, wherein:
the particles to absorb a magnetic field comprise a ferromagnetic material.

19. The mold compound of claim 16, wherein:
the matrix component comprises an epoxy material.

20. A computing device comprising:
a circuit board; and
a package assembly having a first side and a second side disposed opposite to the first side, the first side being coupled with the circuit board using one or more package-level interconnects disposed on the first side, the package assembly including
a die coupled with a package substrate; and
a mold compound disposed on the die;
wherein the mold compound includes a matrix component and particles to absorb a magnetic field.

21. The computing device of claim 20, wherein:
the mold compound comprises at least 70% by volume particles to absorb a magnetic field.

22. The computing device of claim 20, wherein:
the mold compound comprises at least 80% by volume particles to absorb a magnetic field.

23. The computing device of claim 20, wherein:
the die coupled with the package substrate is a first die at least partially embedded in the package substrate and the package assembly further comprises a second die disposed on and electrically coupled to the first die.

24. The computing device of claim 20, further comprising a module that generates a magnetic field; wherein the particles to absorb a magnetic field are configured to shield the die from the magnetic field.

25. The computing device of claim 20, wherein:
the computing device is a mobile computing device including one or more of an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, or a camera coupled with the circuit board.
